(19) United States
(12) Patent Application Publication
(10) Pub. No.: US 2021/0067023 A1
(43) Pub. Date: Mar. 4, 2021

(54) HAPTIC ACTUATOR INCLUDING SHAFT COUPLED FIELD MEMBER AND RELATED METHODS

(71) Applicant: Apple Inc., Cupertino, CA (US)

(72) Inventors: Kathryn K. WOPAT, San Francisco, CA (US); Hari VASUDEVAN, Bangalore (IN)

(21) Appl. No.: 16/989,585

(22) Filed: Aug. 10, 2020

Related U.S. Application Data
(60) Provisional application No. 62/893,966, filed on Aug. 30, 2019.

(51) Int. Cl. H02K 33/18; H05K 5/00

(52) U.S. Cl. CPC H02K 33/18; H05K 5/0017

(57) ABSTRACT

A haptic actuator may include a spool having an opening therein and at least one coil wound on the spool. The haptic actuator may also include a tubular shaft bearing within the opening and a shaft slidable within the tubular shaft bearing. The haptic actuator may further include a field member coupled to the shaft and that includes a frame and at least one permanent magnet carried by the frame and surrounding the at least one coil.

### RELATED APPLICATION

The present application claims the priority benefit of provisional application Ser. No. 62/893,966 filed on Aug. 30, 2019, the entire contents of which are herein incorporated by reference.

### TECHNICAL FIELD

The present disclosure relates to the field of electronics, and, more particularly, to the field of haptics.

### BACKGROUND

Haptic technology is becoming a more popular way of conveying information to a user. Haptic technology, which may simply be referred to as haptics, is a tactile feedback based technology that stimulates a user's sense of touch by imparting relative amounts of force to the user.

A haptic device or haptic actuator is an example of a device that provides the tactile feedback to the user. In particular, the haptic device or actuator may apply relative amounts of force to a user through actuation of a mass that is part of the haptic device. Through various forms of tactile feedback, for example, generated relatively long and short bursts of force or vibrations, information may be conveyed to the user.

### SUMMARY

A haptic actuator may include a spool having an opening therein and at least one coil wound on the spool. The haptic actuator may also include a tubular shaft bearing within the opening and a shaft slidable within the tubular shaft bearing. The haptic actuator may further include a field member that includes a frame and at least one permanent magnet carried by the frame and surrounding the at least one coil.

The spool may include a ferritic material. The tubular shaft bearing may include a ferritic material, for example. The shaft may include a ferritic material.

The at least one coil may have a cylindrical shape, for example. The frame may include a ferritic material. The frame may have a cylindrical shape, for example. The frame may extend over the at least one coil, for example.

A method aspect is directed to a method of making a haptic actuator. The method may include winding at least one coil on a spool having an opening therein and positioning a tubular shaft bearing within the opening. The method may further include slidably positioning a shaft within the shaft bearing, and coupling a field member to the shaft. The field member may include a frame and at least one permanent magnet carried by the frame and positioned to surround the at least one coil.

### BRIEF DESCRIPTION OF THE DRAWINGS

FIG. 1 is a schematic diagram of an electronic device in accordance with an embodiment.

FIG. 2 is a schematic perspective cross-sectional view of a haptic actuator in accordance with an embodiment.

FIG. 3 is a schematic side cross-sectional view of a haptic actuator in accordance with an embodiment in an exemplary implementation.

### DETAILED DESCRIPTION

The present invention will now be described more fully hereinafter with reference to the accompanying drawings, in which preferred embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. Like numbers refer to like elements throughout.

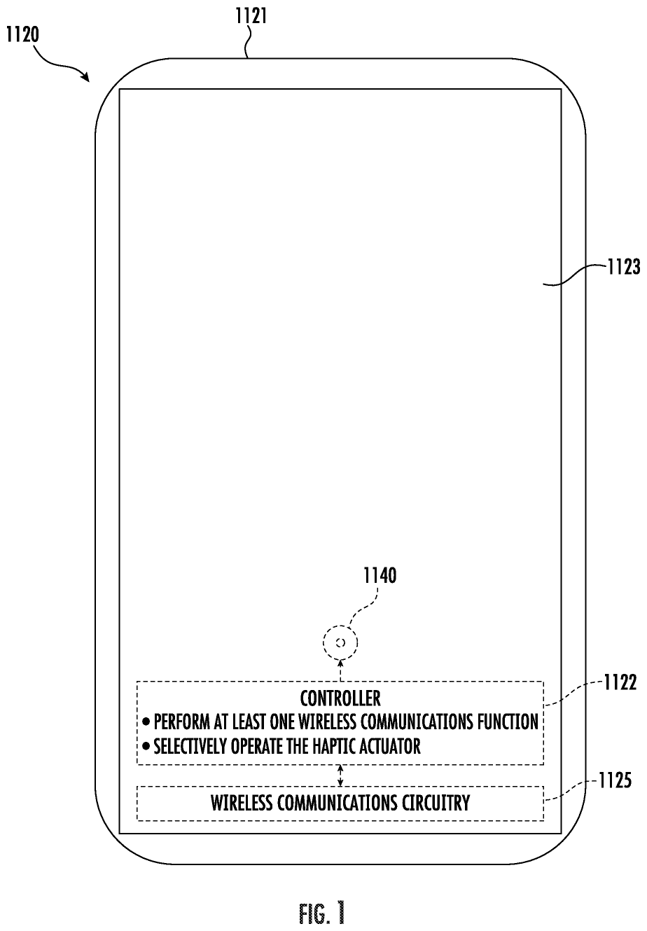

Referring initially to FIG. 1, an electronic device 1120 illustratively includes a device housing 1121 and a controller 1122 or processor carried by the device housing. The electronic device 1120 is illustratively a mobile wireless communications device, for example, a cellular telephone or smartphone. The electronic device 1120 may be another type of electronic device, for example, a wearable device (e.g., a watch), a tablet computer, a laptop computer, etc.

Wireless communications circuitry 1125 (e.g. cellular, WLAN Bluetooth, etc.) is also carried within the device housing 1121 and coupled to the controller 1122. The wireless communications circuitry 1125 cooperates with the controller 1122 to perform at least one wireless communications function, for example, for voice and/or data. In some embodiments, the electronic device 1120 may not include wireless communications circuitry 1125.

A display 1123 is also carried by the device housing 1121 and is coupled to the controller 1122. The display 1123 may be, for example, a light emitting diode (LED) display, a liquid crystal display (LCD), or may be another type of display, as will be appreciated by those skilled in the art. The display 1123 may be a touch display and may cooperate with the controller 1122 to perform a device function in response to operation thereof. For example, a device function may include a powering on or off of the electronic device 1120, initiating communication via the wireless communications circuitry 1125, and/or performing a menu function.

The electronic device 1120 illustratively includes a haptic actuator 1140. The haptic actuator 1140 is coupled to the controller 1122 and provides haptic feedback to the user in the form of relatively long and short vibrations. The vibrations may be indicative of a message received, and the duration and type of the vibration may be indicative of the type of message received. Of course, the vibrations may be indicative of or convey other types of information.

While a controller 1122 is described, it should be understood that the controller may include one or more physical processors and/or other circuitry to perform the functions described herein.

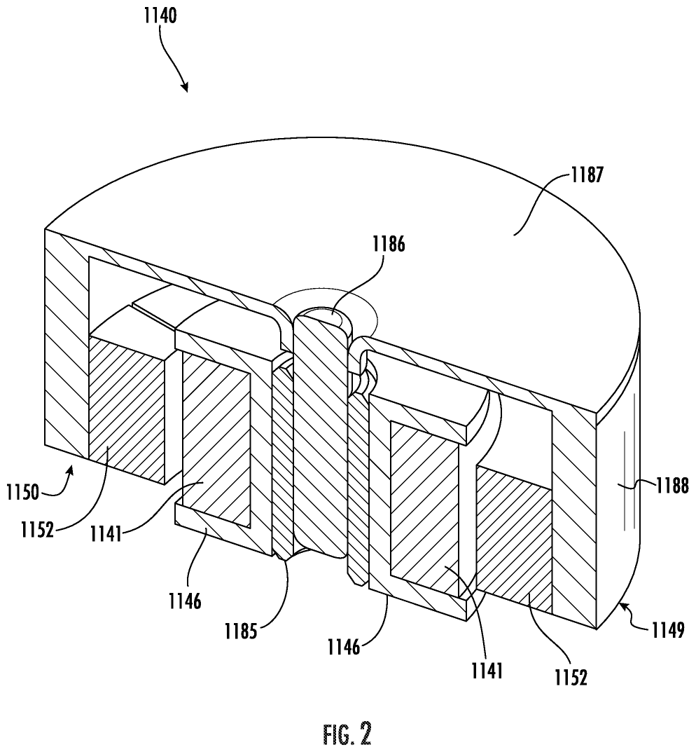

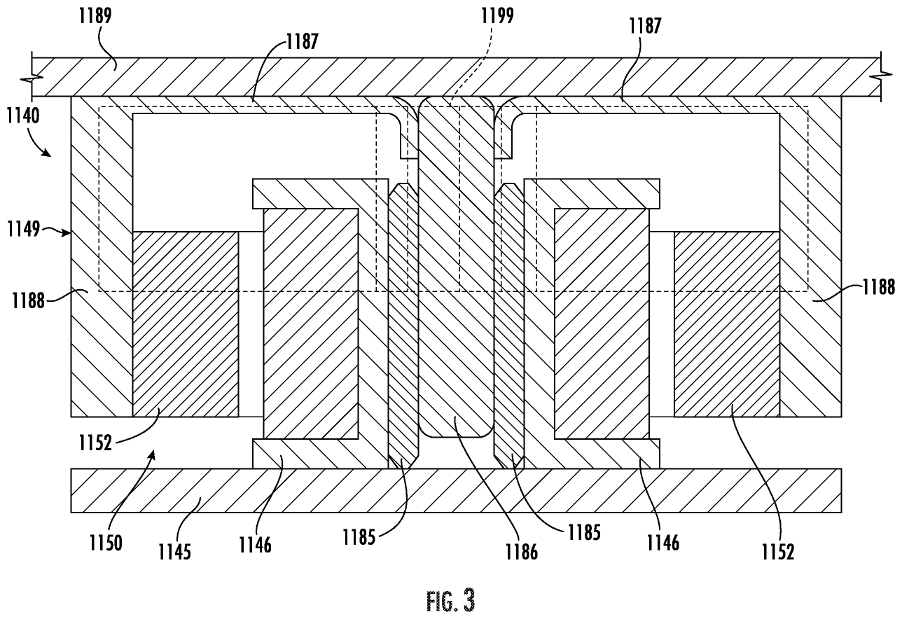

Referring additionally to FIGS. 2 and 3, the haptic actuator 1140 includes a spool 1146 or coil tray that has an opening therein. The spool 1146 may include ferritic material, for example. In some embodiments, the spool 1146 may include other and/or additional materials, for example, non-ferritic materials.

A coil 1141 is wound on the spool 1146. The coil 1141 illustratively has a round or cylindrical shape. While a single coil 1141 is illustrated, it should be understood by those skilled in the art that there may be any number of coils.

A tubular shaft bearing 1185 is within the opening in the spool 1146. The tubular shaft bearing 1185 may also include ferritic material. The tubular shaft bearing 1185 may include other and/or additional materials.

The haptic actuator 1140 also includes a shaft 1186 that is slidable within the tubular shaft bearing 1185. Similarly to the tubular shaft bearing 1185, the shaft 1186 may also include ferritic material.

The haptic actuator 1140 also includes a field member 1150 that is coupled to the shaft 1186. The field member 1150 illustratively includes a frame 1149. The frame 1149 may include ferritic material, for example. The frame 1149 may include other and/or additional material, for example, non-ferritic material. The frame 1149 illustratively has a cylindrical shape and is coupled to the shaft 1186. The frame 1149 has a sidewall 1188, illustratively cylindrical in shape. The frame 1149 also includes a cover 1187 coupled to the sidewall that covers the spool 1146 and coil 1141. The sidewall 1188 extends downwardly (i.e., in the z-axis direction) from the cover 1187.

The field member 1150 also includes a permanent magnet 1152 that is carried by the frame 1149, and more particularly, the downwardly extending sidewall 1188 and spaced apart from and facing the coil 1141. There may be more than one permanent magnet 1152.

In some implementations, the haptic actuator 1140 may be coupled between a substrate 1145 or base and a touchpad 1189 (e.g., for finger-based navigation), for example, to provide haptic feedback in response to downward pressure or a “click” (FIG. 3). In other embodiments or implementations, the haptic actuator 1140 may be positioned between a substrate 1145 and a back of a display, for example, a touch display.

As will be appreciated by those skilled in the art, for applications where a haptic actuator is subjected to a variable load or displacement which causes coils and magnetic components to displace relative to each other, it may be desirable that supporting structures and magnetic circuit components be engineered to achieve desired force and motion constraints. The components used in a supporting structure may perform multiple functions at a same time such as providing the magnetic return path and providing designed stiffness and force response. Accordingly, the haptic actuator 1140 described herein provides a reduced size allowing implementation in space-constrained application. The haptic actuator 1140 provides this space-savings by integrating the suspension components into the magnetic return path, which is illustrated in FIG. 3 by the dashed line 1199.

A method aspect is directed to a method of making a haptic actuator 1140. The method may include winding at least one coil 1041 on a spool 1146 having an opening therein and positioning a tubular shaft bearing 1185 within the opening. The method may further include slidably positioning a shaft 1186 within the tubular shaft bearing 1185, and coupling a field member 1150 to the shaft. The field member 1150 may include a frame 1149 and at least one permanent magnet 1152 carried by the frame and positioned to surround the at least one coil 1141.

While several embodiments have been described herein, it should be appreciated by those skilled in the art that any element or elements from one or more embodiments may be used with any other element or elements from any other embodiment or embodiments. Many modifications and other embodiments of the invention will come to the mind of one skilled in the art having the benefit of the teachings presented in the foregoing descriptions and the associated drawings. Therefore, it is understood that the invention is not to be limited to the specific embodiments disclosed, and that modifications and embodiments are intended to be included within the scope of the appended claims.

That which is claimed is:

1. A haptic actuator comprising:
a spool having an opening therein;
at least one coil wound on the spool;
a tubular shaft bearing within the opening;
a shaft slidable within the tubular shaft bearing; and
a field member coupled to the shaft and comprising a frame and at least one permanent magnet carried by the frame and surrounding the at least one coil.

2. The haptic actuator of claim 1 wherein the spool comprises a ferritic material.

3. The haptic actuator of claim 1 wherein the tubular shaft bearing comprises a ferritic material.

4. The haptic actuator of claim 1 wherein the shaft comprises a ferritic material.

5. The haptic actuator of claim 1 wherein the at least one coil has a cylindrical shape.

6. The haptic actuator of claim 1 wherein the frame comprises a ferritic material.

7. The haptic actuator of claim 1 wherein the frame has a cylindrical shape.

8. The haptic actuator of claim 1 wherein the frame extends over the at least one coil.

9. An electronic device comprising:
a housing;
wireless communications circuitry carried by the housing;
a haptic actuator carried by the housing and comprising
a spool having an opening therein,
at least one coil wound on the spool,
a tubular shaft bearing within the opening,
a shaft slidable within the tubular shaft bearing, and
a field member coupled to the shaft and comprising a frame and at least one permanent magnet carried by the frame and surrounding the at least one coil; and
a controller coupled to the wireless communications circuitry and the haptic actuator and configured to perform at least one wireless communications function and selectively operate the haptic actuator.

10. The electronic device of claim 9 wherein the spool comprises a ferritic material.

11. The electronic device of claim 9 wherein the tubular shaft bearing comprises a ferritic material.

12. The electronic device of claim 9 wherein the shaft comprises a ferritic material.

13. The electronic device of claim 9 wherein the at least one coil has a cylindrical shape.

14. The electronic device of claim 9 wherein the frame comprises a ferritic material.

15. The electronic device of claim 9 wherein the frame has a cylindrical shape.

16. The electronic device of claim 9 wherein the frame extends over the at least one coil.

17. A method of making a haptic actuator comprising:
winding at least one coil on a spool having an opening therein;
positioning a tubular shaft bearing within the opening;
slidably positioning a shaft within the tubular shaft bearing; and
coupling a field member to the shaft, the field member comprising a frame and at least one permanent magnet carried by the frame and positioned to surround the at least one coil.

18. The method of claim 17 wherein the spool comprises a ferritic material.

19. The method of claim 17 wherein the tubular shaft bearing comprises a ferritic material.

20. The method of claim 17 wherein the shaft comprises a ferritic material.

21. The method of claim 17 wherein the at least one coil has a cylindrical shape.

22. The method of claim 17 wherein the frame comprises a ferritic material.

23. The method of claim 17 wherein the frame has a cylindrical shape.

24. The method of claim 17 wherein the frame extends over the at least one coil.
